(19) United States
(12) Patent Application Publication
(10) Pub. No.: US 2012/0057293 A1
(43) Pub. Date: Mar. 8, 2012

(54) Personal Electronic Device Docking Station

(76) Inventor: Thomas Detemple, Planegg (DE)

(21) Appl. No.: 13/038,851

(22) Filed: Mar. 2, 2011

(30) Foreign Application Priority Data
Sep. 3, 2010 (DE) 40 2010 004 093.7
Feb. 21, 2011 (DE) 10 2011 000 848.9

(51) Int. Cl. H05K 7/00

(52) U.S. Cl. 361/679.41

(57) ABSTRACT

The invention discloses a fixture for a mobile electronic device having two clamping elements (2, 4) and an intermediate portion (36, 38, 40) arranged essentially flush thereto. The clamping elements may be shifted or pivoted. Optional, the intermediate portion may be depressed. The intermediate portion may accommodate an image (36), a mirror, a display and/or a control panel.

### CROSS-REFERENCE TO RELATED APPLICATION(S)

This application claims the benefit of German Patent Application No. 10 2011 000 848.9, filed Feb. 11, 2011, the entirety of which is hereby incorporated herein by reference. This application also claims the benefit of German Patent Application No. 40 2010 004 093.7, filed on Sep. 3, 2010, the entirety of which is hereby incorporated herein by reference.

### BACKGROUND OF THE INVENTION

1. Field of the Invention

The present invention relates to a fixture for a mobile electronic device that integrates well in an existing environment and does not require a coupling element mounted on the mobile electronic device.

2. Description of the Related Art

If a mobile electronic device, such as a tablet computer, is not used interactively, it is desired to mount it to a wall to use it as an information display device, such as for weather information, or as a music playback device. Further, the tablet computer may be used for home automation, if it is mounted to the wall. Currently, a plurality of systems for mounting a tablet computer to a wall are known. These systems require partly mounting of a unsightly fixture to the wall disturbing the overall optical impression of the room. Further, such fixtures require that additional coupling elements are mounted to the tablet computer. This causes that the tablet computer becomes bulky, does not abut on a surface, such as a table, and the entire manipulation of the tablet computer is affected. Further, the dimensions of the tablet computer are increased. FIGS. 24 to 30 show fixtures for prior art mobile electronic devices. These fixtures are disadvantageous in that the fixing components of the fixtures protrude unprotected into the room, when the mobile electronic device has been removed from the fixture. On the one hand, such fixing components might get damaged. On the other hand the visible fixing components prevent the prior art fixtures from integrating into a room environment.

Therefore, there is a need for an improved fixture for a mobile electronic device.

### SUMMARY OF THE INVENTION

The disadvantages of the prior art are overcome by the present invention which, in one aspect, is a fixture adapted to hold a mobile electronic device, wherein the fixture comprises a first clamping element arranged pivotally and on which an electric connector is arranged, and a second clamping element arranged pivotally. The first and second clamping elements are adapted to be arranged in their resting position adjacent to an intermediate portion provided between the first clamping element and the second clamping element. The first and second clamping elements hold in their clamping position the mobile electronic device. The first clamping element and the electric connector are adapted such that the electric connector arranged on the first clamping element electronically contacts in the clamping position of the first clamping element a connector of the mobile electronic device. In the resting position of the first clamping element the electronic device is not held by the first and second clamping elements. In the clamping position of the first clamping element the electric connector is pivoted towards the rear of the fixtures.

The first and/or second clamping element(s) may be pivoted between the resting position and clamping position. Preferably, elastic elements are provided which bias the clamping element into the resting position and/or clamping position. Magnets may be provided holding the clamping element in the clamping position and/or resting position. On the clamping elements flexible portions may be provided holding the electronic device frictionally engaged or by force fit. On the clamping elements also elements for providing a form closure or positive locking may be provided holding the electronic device by form closure and positive locking, respectively.

The connector may be arranged on the first clamping element pivotally and/or shiftable with respect to the clamping element. On the fixture a recess may be provided in which the connector is pivoted in the resting position of the first clamping element. Within this recess the connector is protected from contamination and dust. The recess may be provided in the rear portion of the fixture.

An alternative fixture adapted to releasably hold a mobile electronic device comprises a first clamping element and second clamping element. The first and the second clamping elements are adapted to be arranged in their resting position adjacent to an intermediate portion provided between the first clamping element and the second clamping element. The first and second clamping elements releasably hold in their clamping position the mobile electronic device. In the clamping position of the first and second clamping elements an electric connector of the fixture is coupled with an electric connector of the electronic device. The electric connector may be arranged on the first clamping element or in the first clamping element. The intermediate portion is configured such that it may be depressed and at least one of the clamping elements is supported movably in a direction that differs from the direction in which the intermediate portion is depressed. The connector may be arranged on the first clamping element such that it can be pivoted with respect to the first clamping element but essentially cannot be shifted with respect to the first clamping element. The first and second clamping element may be provided with an elastic portion holding the electronic device frictionally engaged or by force fit. Further elements adapted for a form closure or positive locking may be provided on the first and second clamping element holding the mobile electronic device by form closure or positive locking. This embodiment is particularly suited if the fixture shall be mounted to a wall, a piece of a furniture or a mural.

A further fixture adapted to releasably hold a mobile electronic device comprises a first clamping element and a second clamping element, wherein the first and second clamping elements are adapted to be arranged adjacent to an intermediate portion, provided between the first clamping element and the second clamping element. The first and second clamping elements releasably hold in their clamping position the mobile electronic device. In the clamping position of the first and second clamping elements an electric connector of the fixture is coupled with an electric connector of the electronic device. The electric connector may be arranged on the first clamping element or in the first clamping element. The intermediate portion is adapted that it can be depressed, and at least one blind surrounding the electric connector in the resting position at least partly is supported movable in a direction differing from the direction for depressing the intermediate portion to an open position of the blind, in which the electric connector is accessible.

This fixture is also suited to be mounted on a mural, a wall or a wall of a piece of furniture or room decoration element. In this embodiment the actual clamping portion is not moved, but merely a blind is moved in order to uncover the electric connector such that mobile electronic device can be mounted in the fixture in order that the electric connector of the fixture and the electric connector of the mobile electronic device cause a conducting connection. The electric connector of the fixture is in all embodiments electrically coupled with the electric connector of the mobile electronic device, if the mobile electronic device is held by the fixture. Preferably, the electric connector of the fixture is pushed into the electric connector of the mobile electronic device. In all embodiments the first and second clamping elements may be arranged in their resting position, in which the portable electronic device is not held by the first and second clamping elements, at least one side thereof essentially flush with the intermediate portion.

The fixture may comprise mounting means. The mounting means may be adapted such, that the first and second clamping elements can be arranged on or in a wall, a mural, a piece of furniture and/or a room decoration element. The clamping elements may be arranged such that they protrude from the mural, the wall, the piece of furniture and/or the room decoration element. The first and second clamping elements may be arranged essentially flush with a surface of the intermediate portion, if the first and second clamping elements protrude from the mural, wall, piece of furniture and/or room decoration element. The first and second clamping elements may be arranged flush with the mural, wall, piece of furniture and/or room decoration element. In this case the intermediate portion may be considered forming part of the piece of furniture and/or of a room decoration element or can be a piece of furniture and/or a room decoration element.

On the mounting means shifting means may be arranged causing that the distance of the clamping elements may be adjusted. Thereby, the fixture may be adapted to different mobile electronic devices.

The intermediate portion may be a receptacle for a image, a mirror, a key pad and/or display device. The key pad and/or the display device may be part of a home automation system. Since the intermediate portion comprises a receptacle for an image, a mirror, a key pad and/or a display the fixture may perform a function, when the fixture does not hold a mobile electronic device, if the user has removed the device from the fixture. This function performed by the intermediate portion of the fixture integrates in an office environment and/or room (living room) environment. The intermediate portion can ensure that the office environment and/or the room is not affected by components of the fixture. Since the first and second clamping elements are formed flush with the intermediate portion, the integration of the fixture into the office environment and/or the room is improved.

The fixture may comprise a rotation device connecting the first and second clamping elements rotatably with the mounting means. This enables that the mobile electronic device may be pivoted, e.g. about 90°, such that the screen of the mobile device may be held in a portrait mode or landscape mode. The intermediate portion may be connected to the mounting means by the rotation device. Thereby, the first and second clamping elements as well as the intermediate portion may be rotated synchronously.

The fixture may comprise a stand element adapted to position the first and second clamping elements such on a surface that the mobile electronic device is held in an oblique angle to the surface. The stand element enables that the fixture positions the mobile electronic device in an oblique angle with respect to a table such that the operator may operate and/or use the mobile electronic device on a table. The stand can be clapped or folded from the electronic device.

The fixture may comprise an electronic equipment, wherein the electronic equipment may comprise a radio network node, a power line network node, a radio router (WLAN Router) and/or a component of a home automation system. Thereby, a versatile fixture is achieved that can perform an electronic functionality even if no mobile electronic device is held by the fixture.

The fixture may retain a tablet computer, such as the popular iPad® marketed by Apple Inc.

In the following, the invention is explained by non-limiting embodiments under reference to the enclosed figures. The expressions describing the spatial arrangement, such as in front, behind, beside, above, under etc. are used for the purposes of description and are not to be construed limiting.

These and other aspects of the invention will become apparent from the following description of the preferred embodiments taken in conjunction with the following drawings. As would be obvious to one skilled in the art, many variations and modifications of the invention may be effected without departing from the spirit and scope of the novel concepts of the disclosure.

### BRIEF DESCRIPTION OF THE FIGURES OF THE DRAWINGS

FIG. 1 is a front view of the first embodiment of the invention.

FIG. 2 is a side view of the first embodiment of the invention.

FIG. 3 is a bottom view of a fixture according to the present invention.

FIG. 4 is a fixture according to the first embodiment of the invention holding a mobile electronic device.

FIG. 5 is a side view of the first embodiment of the invention holding a mobile electronic device.

FIG. 6 is a perspective view of the first embodiment of the invention.

FIG. 7 is an exploded view of the first embodiment of the invention.

FIG. 8 is a first embodiment of the invention, in which the distance of the clamping elements may be adjusted.

FIG. 9 is a perspective view of the second embodiment of the invention.

FIG. 10 is a perspective view of the second embodiment of the invention in which the clamping elements are located in the clamping position.

FIG. 11 is a perspective view of the second embodiment of the invention which holds a mobile electronic device.

FIG. 12 is a perspective view of the third embodiment of the invention.

FIG. 13 is a plan view of the third embodiment of the invention.

FIG. 14 is a side view of the third embodiment of the invention.

FIG. 15 is a plan view of the third embodiment of the invention holding a mobile electronic device.

FIG. 16 is a side view of the third embodiment of the invention holding a mobile electronic device.

FIG. 17 is a rear view of the third embodiment of the invention.

FIG. 18 is a perspective view of the fourth embodiment of the invention.

FIG. 19 is a perspective view of the fourth embodiment of the invention.

FIG. 20 is an exploded view of the fourth embodiment of the invention.

FIG. 21 is a fixture according to the present invention with or in an electronic device.

FIGS. 22-23 are respective diagrams in which the fixture according to the present invention is arranged on a stand.

FIGS. 24-30 show prior art fixtures.

### DETAILED DESCRIPTION OF THE INVENTION

A preferred embodiment of the invention is now described in detail. Referring to the drawings, like numbers indicate like parts throughout the views. Unless otherwise specifically indicated in the disclosure that follows, the drawings are not necessarily drawn to scale. As used in the description herein and throughout the claims, the following terms take the meanings explicitly associated herein, unless the context clearly dictates otherwise: the meaning of “a,” “an,” and “the” includes plural reference, the meaning of “in” includes “in” and “on.”

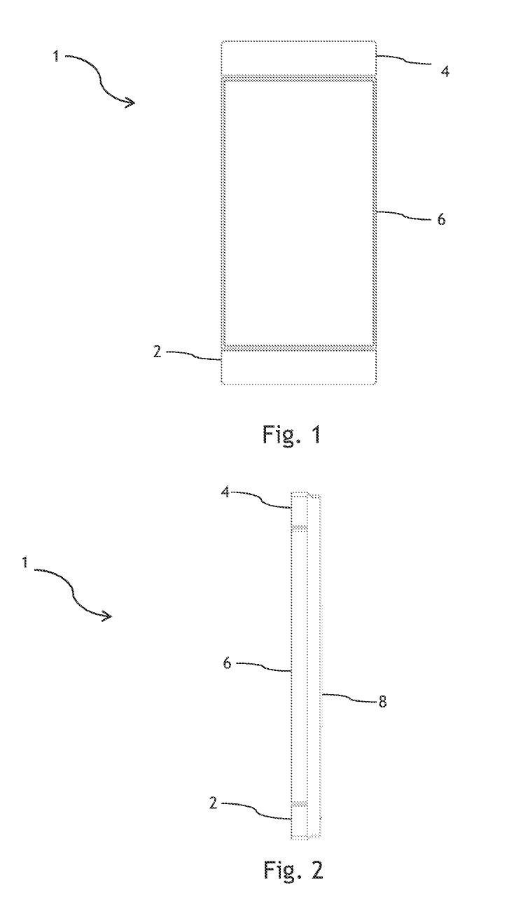

FIG. 1 shows a plan view of the fixture 1 according to a first embodiment of the invention. A first clamping element 2 is arranged under an intermediate portion 6, and a second clamping element 4 is arranged above the intermediate portion 6. The surfaces of the first clamping element 2 and the second clamping element 4 are essentially flush to the surfaces of the intermediate portion. Particularly, the front and lateral surfaces of the clamping elements 2, 4 and of the intermediate portion 6 are flush to each other. The intermediate portion 6 can be configured that an image, for example a photography or a drawing, or a mirror can be accommodated. In the resting position of the first clamping element 2 and of the second clamping element 4 shown in FIG. 1 the fixture according to the present invention integrates in an office environment or living room environment without disturbing mechanical or electric components of the fixture affecting the room.

FIG. 2 shows a side view of a fixture 1 according to the first embodiment of the present invention. Behind the intermediate portion 6 fixing means 8 are arranged. The first clamping element 2 and the second clamping element 4 are formed on their front faces essentially flush with the intermediate portion 6.

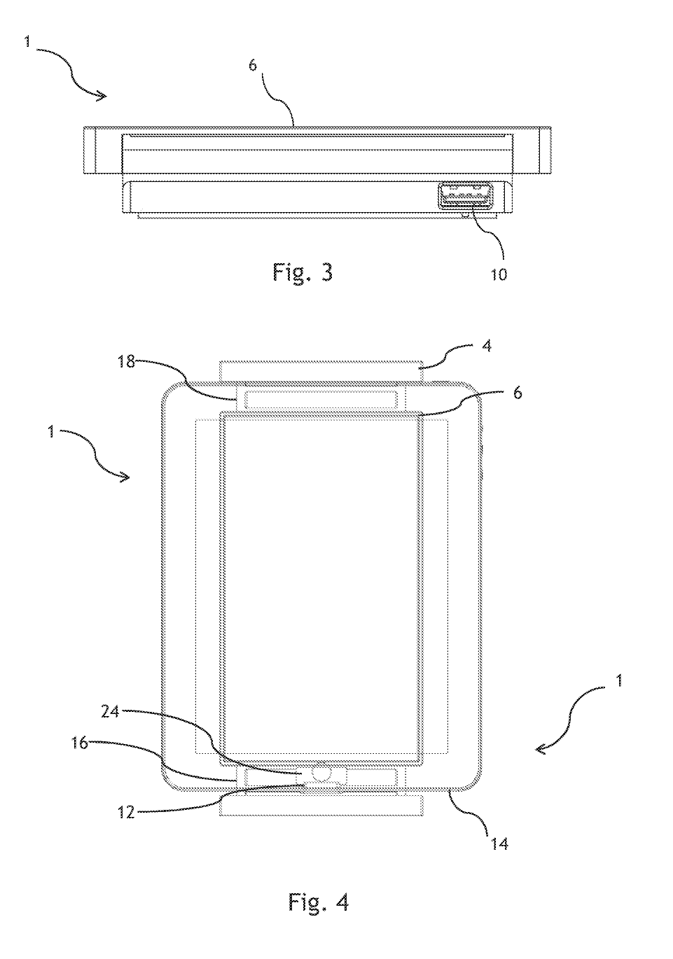

FIG. 3 shows a bottom view of the fixture. Below the clamping element 2 an electric connector 10 is arranged, such as a so called USB interface, an Apple Dock connector, micro USB etc.

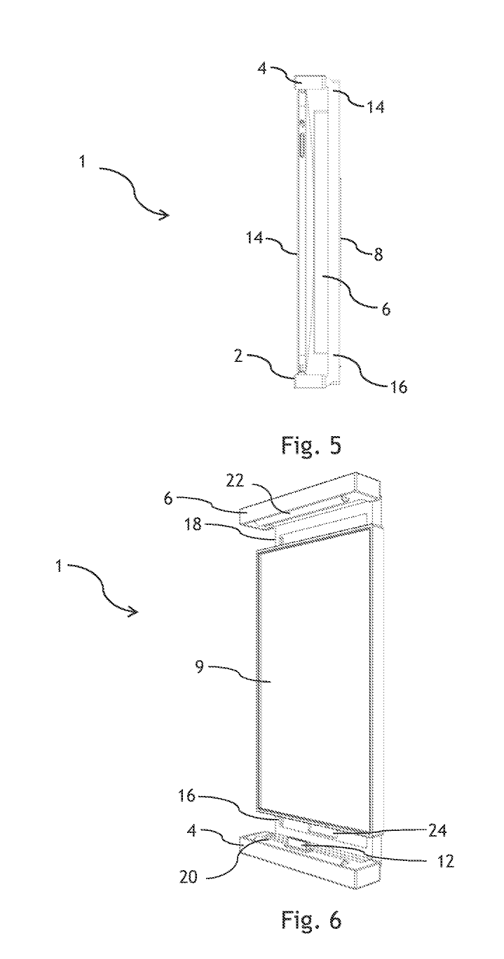

FIGS. 4 and 5 show the first embodiment of the fixture 1 when holding a mobile electronic device. FIG. 6 shows a first embodiment of the fixture in a condition in which the clamping elements 2, 4 are positioned in the clamping position and no mobile electronic device is held therein.

The first clamping element 2 and the second clamping element 4 are in their clamping position. The clamping elements clamp the mobile electronic device 14 at opposite sides of the mobile electronic device. An electric connector 12 of the fixture that may be arranged pivotally and/or shiftably on the first clamping element 2 is coupled with an electric connector (not shown) of the mobile electronic device. The first clamping element 2 and the second clamping element 4 are pivoted relative to the resting position shown in FIGS. 1 to 3 about approximately 90° into the clamping position. The first clamping element 2 is connected with the intermediate portion 6 by a first chassis portion 16, and the second clamping element 4 is connected with the intermediate portion 16 by a second chassis portion 18. The first chassis portion 16 comprises a recess 24, in which the electric connector may be pivoted in the resting position. Therein, the electric connector 12 is protected against dirt.

On the first clamping element 4 a first elastic portion 20 and on the second clamping element 6 a second elastic portion 22 is arranged. Thereby, the mobile electronic device may be clamped frictionally engaged and by force closure, respectively.

Magnets (not shown) may be provided retaining the first clamping element 4 and the second clamping element 6 in their resting position shown in FIG. 1. Further, elastic elements may be provided pushing or pulling the first clamping element and the second clamping element, respectively in their clamping position, as soon as the first clamping element 4 or the second clamping element 6 have been moved manually from its resting position.

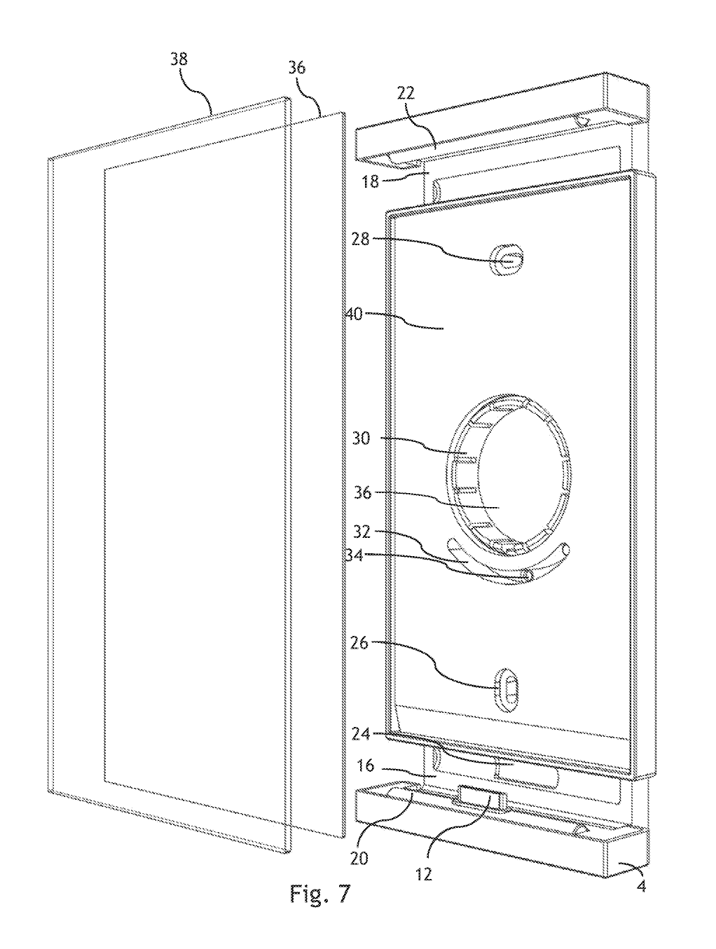

FIG. 7 shows an exploded view of the first embodiment of the invention. The description of elements explained before is not repeated. The intermediate portion is arranged on a rotation device 30. The rotation device 30 may comprise a plurality of latching elements having latching tabs latching the intermediate portion. The intermediate portion may comprise an opening 36 having a circular step, in which the latching tabs of the latching elements of the rotation device 30 latch. The opening 36 may be formed in a chassis body 40 of the intermediate portion 6. In the chassis body 40 an arc shaped slot 32 or an arc shaped recess may be formed accommodating a pin 34 of the rotation device 30. The slot or the recess 32 acts as stop such that the chassis body and accordingly the first and second clamping elements 2, 4 and the intermediate portion 6 may be rotated merely about a predetermined angle, such as 90°.

The chassis body 40 comprises first and second openings 26, 28 provided for mounting the fixtures by screws to a wall if it is desired that the chassis body, the first clamping element and the second clamping element may not be rotated. More than two fastening openings may be provided, for example four fastening openings.

A transparent body 38 may be fixed to the chassis body 40. The transparent body 38 may fix an image 36 on the chassis body 40. The image 36 may be a photography, a drawing etc.

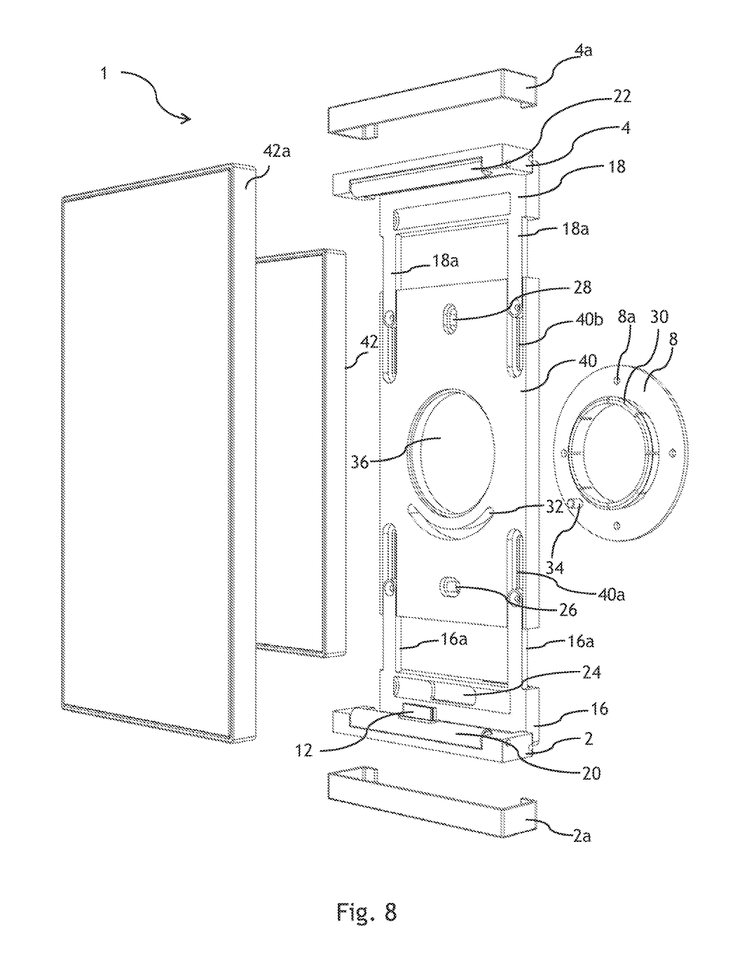

FIG. 8 shows a further exploded view of a fixture l′ of the first embodiment of the invention. In this embodiment of the invention the distance between the first clamping element 2 and the second clamping element 4 may be adjusted. A description of elements described above under reference to FIGS. 1 to 7 is not repeated. The rotation device 30 is formed integrally with the mounting means 8 comprising a plurality of openings 8a. The mounting means 8 can be fixed by screws passing through the openings 8a to a wall.

The first clamping element 2 is connected slidably with the chassis body 40 over the first chassis portion 16 having at least one protrusion 16a and arm 16a, respectively, wherein the protrusion 16a may be moved or slid within a recess 40a of the chassis body. Thereby the distance of the first clamping element 2 from the chassis body 40 and from the second clamping element 4 may be adjusted. An opening may be located in the protrusion 16a through which a screw can be passed fixing the distance of the first clamping element 2 from the chassis body 40. In the alternative, latching means may be provided on the protrusion 16a and in the recess 40a. The second clamping element 4 is connected to the chassis body 40 by an optional second chassis portion 18 with at least one optional protrusion 18a and arm 18a, respectively. The protrusion 18a may be accommodated by an optional recess 40b in the chassis body. Accordingly, both the distance of the first clamping element 2 to the chassis body as well as the distance of the second clamping element 4 to the chassis body 40 may be adjusted by sliding the respective portion 16a, 18a in the respective recess 40a, 40b in the chassis body 40. Also in the protrusion 18a an opening may be located through which a screw passes by which the distance of the second clamping element from the chassis body is fixed. In the alternative, latching means may also be provided at the protrusion 18a and in the recess 40b. It is not necessary that both the first clamping element 2 as well as the second clamping element 4 are designed slidable or movable with respect to the chassis body 40. It is sufficient, if merely one of the clamping elements is movable with respect to the chassis body. Thus, the first clamping element 2 or the second clamping element 4 may be arranged movable with respect to the chassis body 40.

This embodiment of the invention comprises at least one frame body 42, 42a that can be mounted to the chassis body 40. A plurality of frame bodies may foreseen 42, 42a that are mounted depending on the distance of the clamping elements 2, 4 on the chassis body 40 for mounting the respective frame body 42, 42a on the chassis body ensuring that the clamping elements 2, 4 are in their resting position flush with the frame body 42, 42a forming in this case the intermediate portion. Thus, it is possible that the fixture according to the present invention may be used with a plurality of different types of mobile electronic devices.

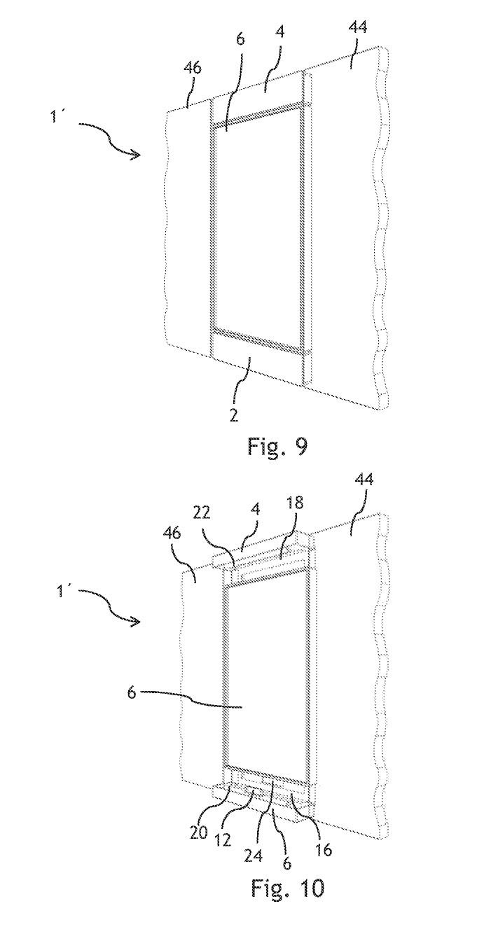

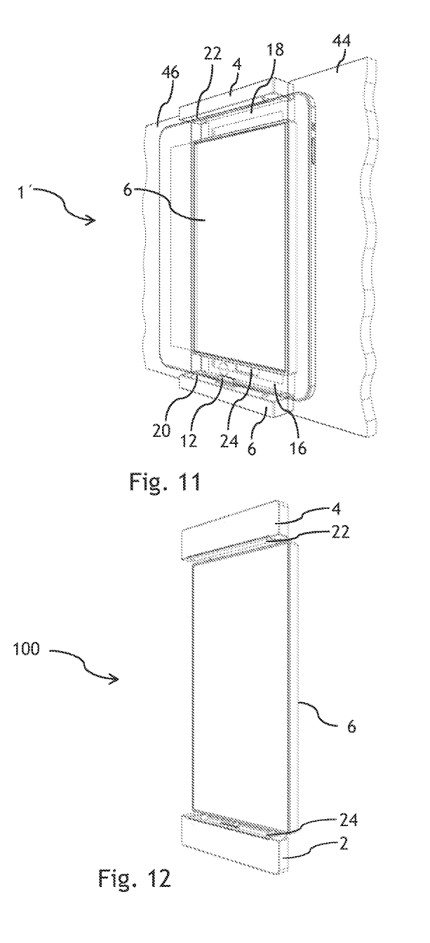

FIGS. 9 to 11 show that the fixture according to the present invention is arranged according to a second embodiment of the invention flush to a wall, a mural, a portion of a piece of furniture and/or a portion of a room decoration element. FIGS. 9 to 11 show an intermediate portion 6, forming part of the fixture according to the present invention. This does not have to be the case. The intermediate portion 6 can also be part of the mural, the wall, the piece of furniture and/or the room decoration element. The room decoration element may be a blind, a picture or any other object placed in a room. The fixture according to the present invention is suitable for flush mounting or buried amounting. It is possible that the cables for charging the accumulator of the mobile electronic device and/or for communicating with the mobile electronic device are installed buried under the plaster. With respect to description of the further elements of the fixture, reference is made to description of FIGS. 1 to 8.

FIGS. 12, 13 and 14 show a fixture 100 according to a third embodiment of the invention. In this embodiment the intermediate portion arranged between the first clamping element 2 and the second clamping element 4 is formed depressible. I.e., the intermediate portion 6 may be moved orthogonal to a line running through the first clamping element 2 and the second clamping element 4, particularly running through the center of the first clamping element 2 and the center of the second clamping element 4. Elastic elements may be provided pressing the intermediate portion 6 outwardly, i.e. to the front face of the clamping elements 2 and 4 such that the front faces and lateral faces of the intermediate portion 6 are essentially flush to the surfaces of the clamping elements 2, 4. In this embodiment the electric connector 12 may be located in the resting position of the first clamping element 2 within the clamping element 2.

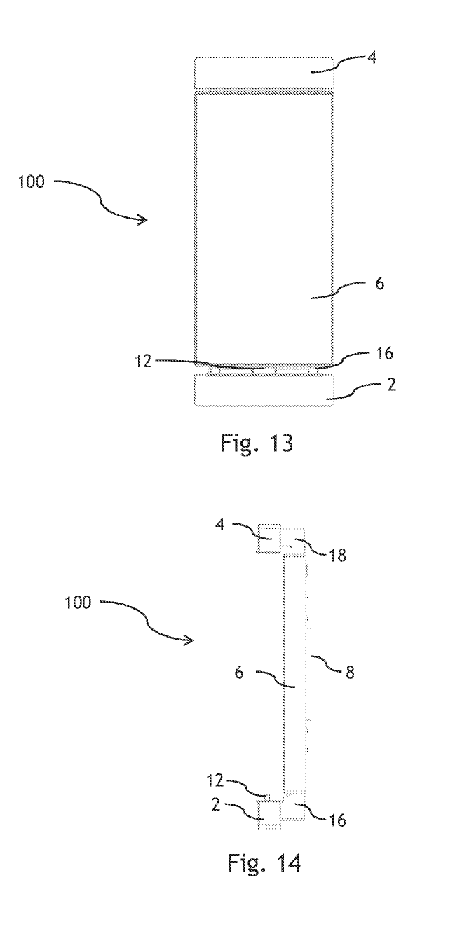

FIGS. 13 and 14 show that the first clamping element 2 is shifted from its resting position downwardly, wherein FIG. 13 is a plan view and FIG. 14 is a side view. The first clamping element 2 is movable along the first chassis portion 16. The second clamping element 4 is arranged on the intermediate portion 6 by the second chassis portion. A mounting means 8 is arranged at the intermediate portion 6.

The electric connector 12 may be mounted essentially not shiftably, but pivotably with respect to the first clamping element.

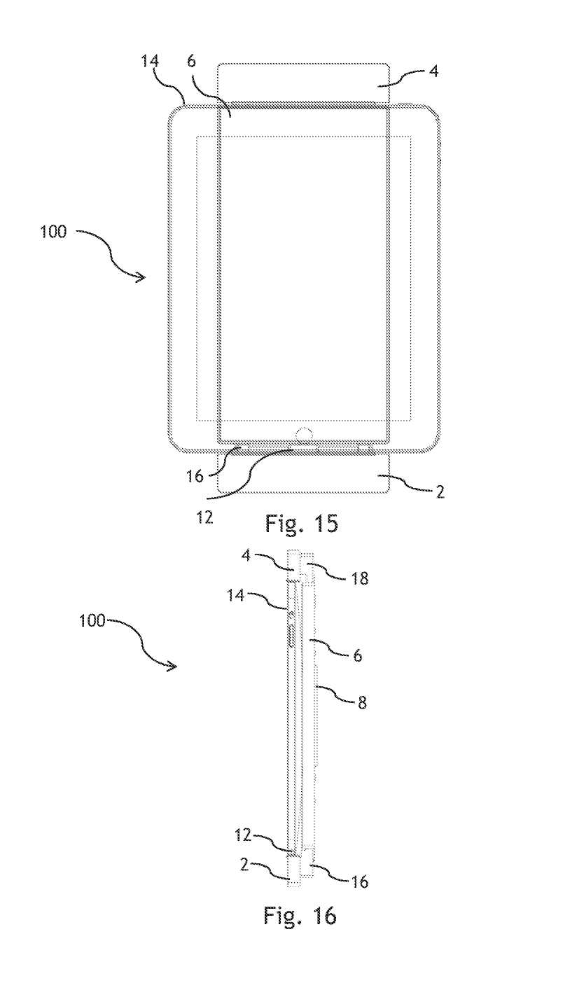

FIGS. 15 and 16 show how the mobile electronic device is held by the third embodiment of the fixture, wherein FIG. 15 is a plan view and FIG. 16 is a side view. The mobile electronic device is held by the first clamping element 2 and the second clamping element at opposite sides of the mobile device 14. The electric connector 12 of the fixture may be coupled electrically with an electric connector (not shown) of the mobile electronic device.

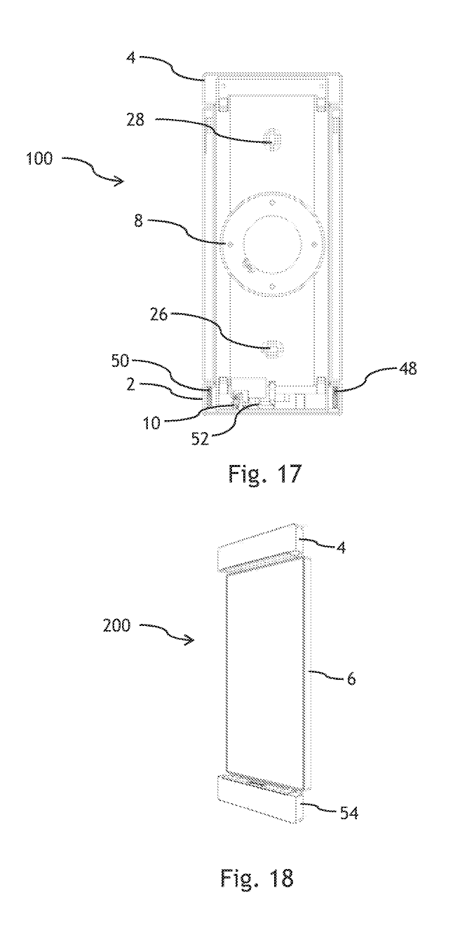

FIG. 17 shows a rear view of the third embodiment of the invention. Elements described before under reference to FIGS. 1 to 16 are not described separately but reference is made to their description above. The first clamping element is pressed by springs 48, 50 towards the intermediate portion 6. As soon as the second clamping element is shifted downward, as is shown in FIGS. 15 and 16, it exerts due to the extension of the springs 48, 50 a clamping force holding the mobile electronic device between the first clamping element 2 and the second clamping element 4. Further, the connector 10 may be arranged on the chassis body 40 of the intermediate portion 6. The connector 10 may be connected with an electric connector 12 of the fixture by a cable 52 or a flexible PCB.

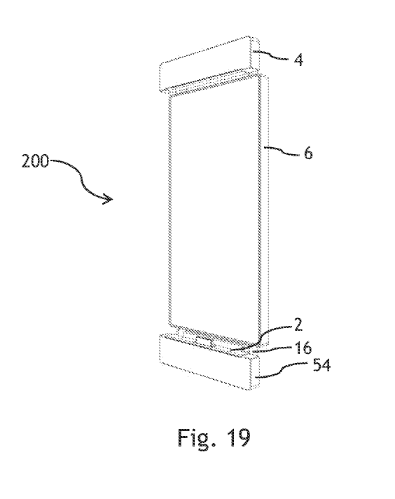

With reference to FIGS. 18 to 20 a fourth embodiment 200 of the invention is discussed. The fourth embodiment of the invention corresponds essentially to the third embodiment 100 of the invention. In contrast to the third embodiment the first clamping element 2 is arranged in the fourth embodiment rigidly and a blind 54 connected with the first clamping element 2 is supported shiftably. FIG. 18 shows the blind 54 in its resting position in which the blind 54 surrounds the electric connector 12 at least partially. The intermediate portion is located in its depressed position in which it is distal from the surface of the first clamping element 2 and the surface of the second clamping element 4. In the open position of the blind shown in FIG. 19 the mobile electronic device may be inserted such that it can be clamped by the first clamping element 2 and the second clamping element 4.

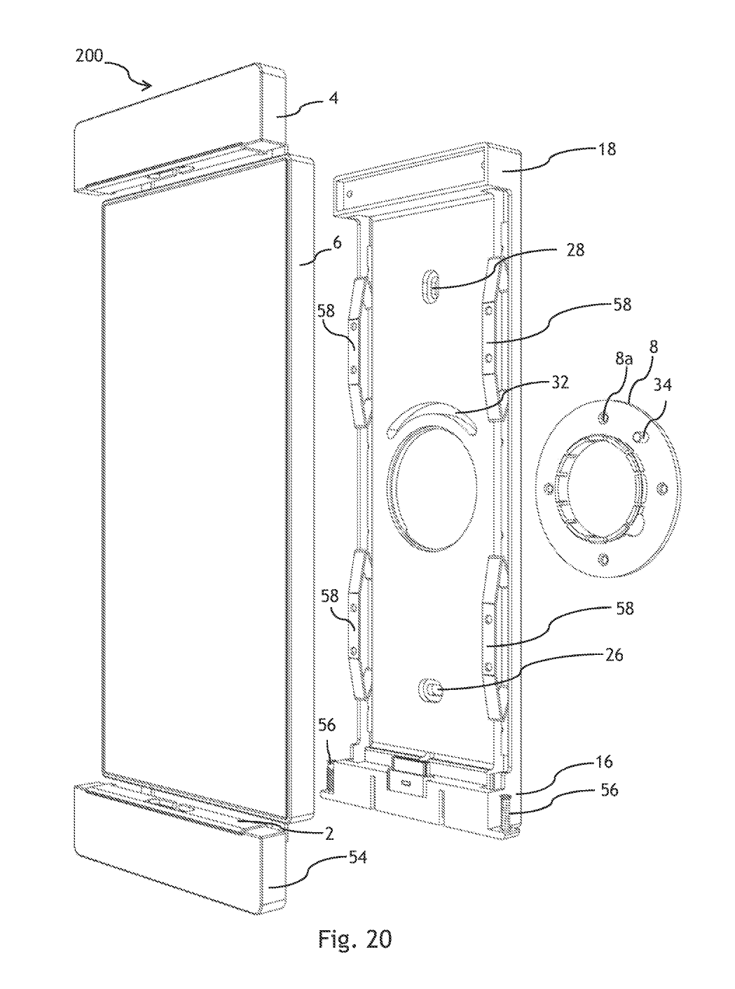

FIG. 20 shows an exploded view of the fourth embodiment of the invention that is similar to the first and particularly third embodiment. Therefore, elements described with respect to FIGS. 1 to 19 are not described anew, but reference is made to their above description. On the chassis body 40 and particularly on the first chassis portion 16 springs 56 are arranged shifting the blind 54 upwards in its resting position.

Further, spring elements 58 are shown pressing the intermediate portion 6 outwardly, such that its front face and lateral faces are essentially flush with the front face and lateral faces of the first clamping element 2, the second clamping element 4 and the blind 54. It is to be noted that the spring elements 56 may also be applied in the third embodiment of the invention.

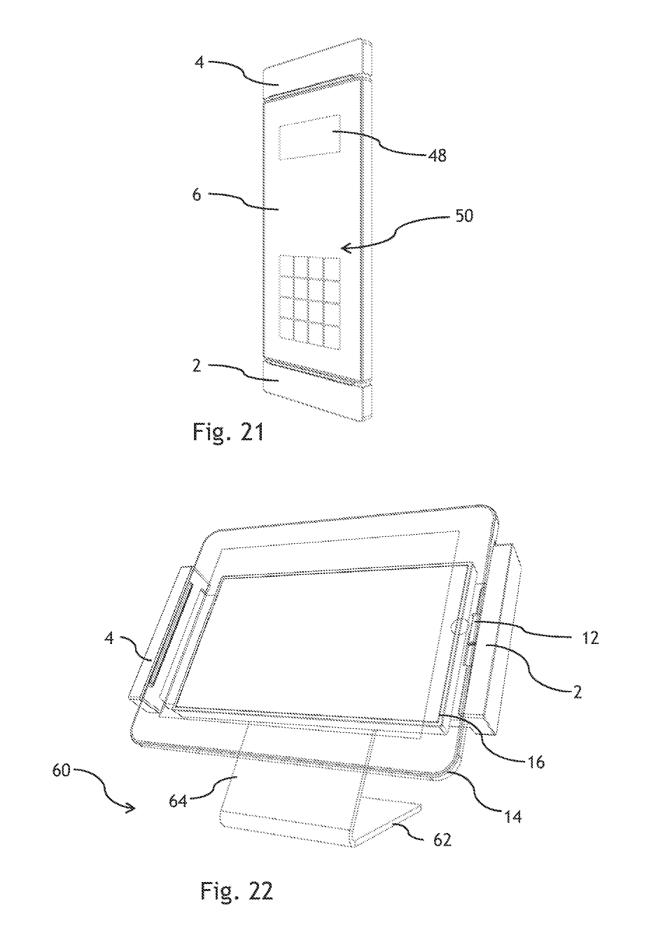

As in the first embodiment of the invention the intermediate portion 6 may also comprise or accommodate in the second, third and fourth embodiment of the invention an image, such as a photo, a drawing etc, or a mirror. FIG. 21 shows that the intermediate portion 6 comprises a display 48 and a control panel 50. The control 50 and the display 48 may be associated to any electric equipment, such as a radio network node, a power line network node, a radio router and/or a component of a home automation system. It is to be noted that such configuration of the intermediate portion is possible in any embodiment of the invention.

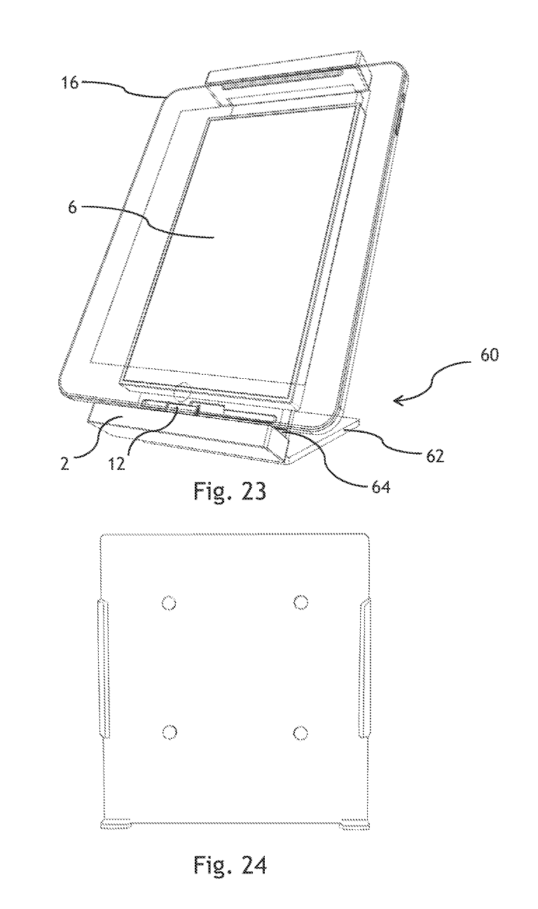

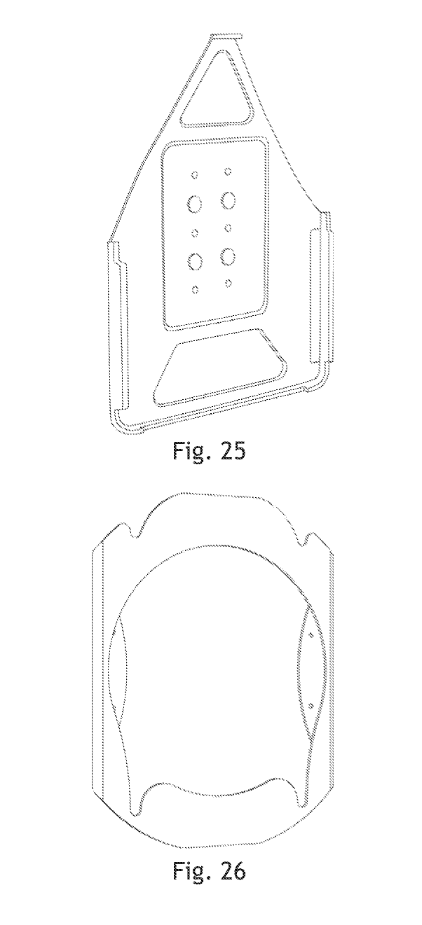

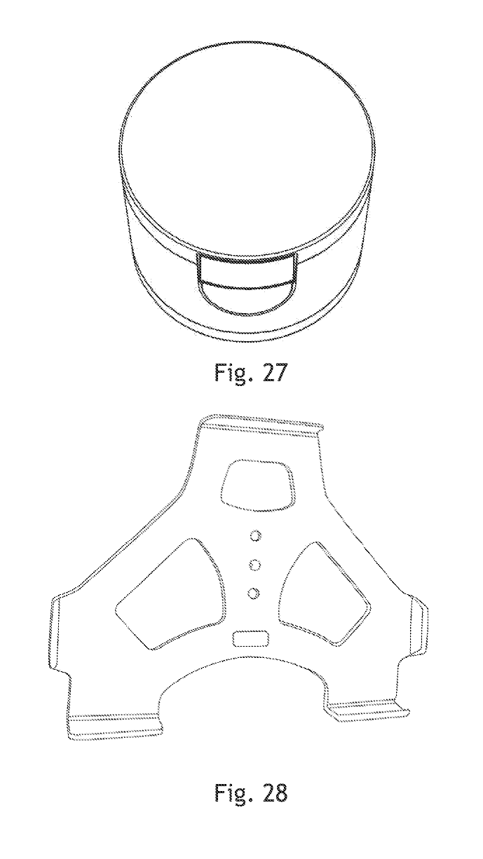

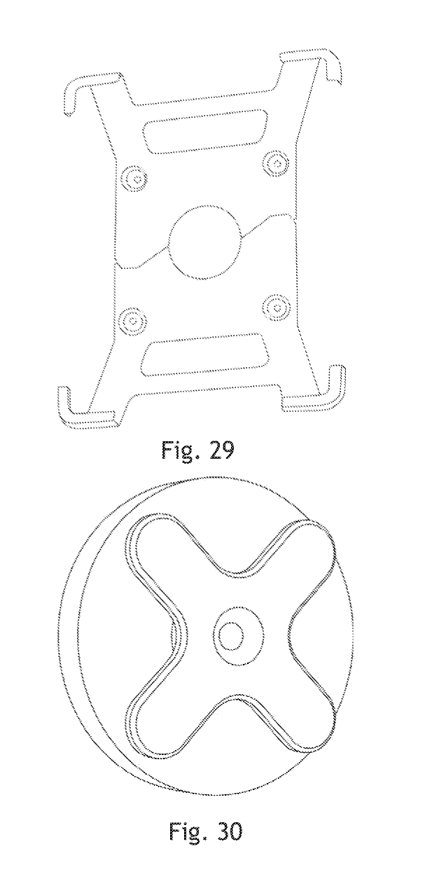

FIGS. 22 and 23 show that the fixture is mounted to a stand 60 having a foot 62 and a holding portion 64. The mobile electronic device is held by a first clamping element 2 and a second clamping element 4. The electric connector 12 of the fixture is connected to an electric connector (not shown) of the mobile electronic device. Accordingly, the mobile electronic device may be held by the stand 60 oblique such that is may be positioned on a table (not shown) by the foot 62.

In all embodiments the outer shells of the clamping elements may be formed removable or exchangeable.

It is to be understood that the features of the single embodiments can be arbitrarily combined.

The fixture according to the present invention protects the electric connector of the fixture from dirt. The intermediate portion 6 may fulfill any function, such as holding an exchangeable image, accommodating a mirror, comprising a control panel and/or comprising a display. Accordingly, the inventive fixture fulfills a technical function as soon as the mobile electronic device is removed from the fixture. Further, the fixture integrates in an existing room environment, if no electronic device is clamped by it.

The above described embodiments, while including the preferred embodiment and the best mode of the invention known to the inventor at the time of filing, are given as illustrative examples only. It will be readily appreciated that many deviations may be made from the specific embodiments disclosed in this specification without departing from the spirit and scope of the invention. Accordingly, the scope of the invention is to be determined by the claims below rather than being limited to the specifically described embodiments above.

What is claimed is:

1. A fixture adapted to releasably hold a mobile electronic device, comprising:
a first clamping element arranged pivotally and on which a second connector is mounted; and
a second clamping element arranged pivotally;
wherein the first and second clamping elements are configured to be arranged in their resting position adjacent to an intermediate portion provided between the first clamping element and the second clamping element;
the first and second clamping elements releasably hold in their clamping position the mobile electronic device,
the first clamping element and the electric connector are configured that the electric connector mounted to the first clamping element establishes in the clamping position of the first clamping element an electric connection to a connector of the mobile electronic device and
in the resting position of the first clamping element the electric connector is pivoted towards the rear of the fixture, wherein in the resting position the mobile electronic device is not held by the first and second clamping elements.

2. The fixture of claim 1, further comprising a mounting means adapted such that the first and second clamping elements may be mounted on or in a mural, a wall, a piece of furniture and/or a room decoration element.

3. The fixture of claim 1, wherein the intermediate portion comprises a receptacle for an image, a mirror, a key pad and/or a display.

4. The fixture of claim 1, wherein the intermediate portion is part of a piece of furniture and/or a room decoration element.

5. The fixture of claim 1, wherein the first and second clamping elements are arranged in their resting position, in which the portable electronic device is not held by the first and second clamping elements, at least one face thereof essentially flush with the intermediate portion.

6. The fixture of claim 1, further comprising a rotation device connecting the first and second clamping element rotatably with the mounting means.

7. The fixture of claim 1, further comprising a stand element adapted to position the first and second clamping elements such on a surface that the mobile electronic device is held in an oblique angle with respect to the surface.

8. The fixture of claim 1, further comprising an electronic device, wherein the electronic device may comprise a selected one of a radio network node, a power line network node, a radio router or a component of a home automation system.

9. A fixture adapted to releasably hold a mobile electronic device, comprising:
a first clamping element; and
a second clamping element,
wherein the first and second clamping element are configured to be arranged in their resting position adjacent to an intermediate portion provided between the first clamping element and the second clamping element,
the first and second clamping elements releasably hold in their clamping position the mobile electronic device, and an electric connector of the fixture is coupled in the clamping position with an electric connector of the mobile electronic device, wherein
the intermediate portion is configured to be depressed and at least one of the clamping elements is supported shiftably in a direction differing from the direction of depressing the intermediate portion.

10. The fixture of claim 9, further comprising a mounting means adapted such that the first and second clamping elements may be mounted on or in a mural, a wall, a piece of furniture and/or a room decoration element.

11. The fixture of claim 9, wherein the intermediate portion comprises a receptacle for an image, a mirror, a key pad and/or a display.

12. The fixture of claim 9, wherein the intermediate portion is part of a piece of furniture and/or a room decoration element.

13. The fixture of claim 9, wherein the first and second clamping elements are arranged in their resting position, in which the portable electronic device is not held by the first and second clamping elements, at least one face thereof essentially flush with the intermediate portion.

14. The fixture of claim 9, further comprising a rotation device connecting the first and second clamping element rotatably with the mounting means.

15. The fixture of claim 9, further comprising a stand element adapted to position the first and second clamping elements such on a surface that the mobile electronic device is held in an oblique angle with respect to the surface.

16. The fixture of claim 9, further comprising an electronic device, wherein the electronic device may comprise a selected one of a radio network node, a power line network node, a radio router or a component of a home automation system.

17. A fixture adapted to releasably hold a mobile electronic device comprising:
a first clamping element; and
a second clamping element,
wherein the first and second clamping element are configured to be arranged adjacent to an intermediate portion provided between the first clamping element and the second clamping element,
the first and second clamping elements releasably hold in their clamping position the mobile electronic device, and an electric connector of the fixture is coupled in the clamping position with an electronic connector of the mobile electronic device, wherein
the intermediate portion is adapted to be depressed and at least one blind surrounding the electric connector in the resting position at least partly is supported shiftably in a direction differing from the direction of depressing the intermediate position to an open position of the blind, in which the electric connector is accessible.

18. The fixture of claim 17, further comprising a mounting means adapted such that the first and second clamping elements may be mounted on or in a mural, a wall, a piece of furniture and/or a room decoration element.

19. The fixture of claim 17, wherein the intermediate portion comprises a receptacle for an image, a mirror, a key pad and/or a display.

20. The fixture of claim 17, wherein the intermediate portion is part of a piece of furniture and/or a room decoration element.

21. The fixture of claim 17, wherein the first and second clamping elements are arranged in their resting position, in which the portable electronic device is not held by the first and second clamping elements, at least one face thereof essentially flush with the intermediate portion.

22. The fixture of claim 17, further comprising a rotation device connecting the first and second clamping element rotatably with the mounting means.

23. The fixture of claim 17, further comprising a stand element adapted to position the first and second clamping elements such on a surface that the mobile electronic device is held in an oblique angle with respect to the surface.

24. The fixture of claim 17, further comprising an electronic device, wherein the electronic device may comprise a selected one of a radio network node, a power line network node, a radio router or a component of a home automation system.
